(19) United States
(12) Patent Application Publication
(10) Pub. No.: US 2017/0269420 A1
(43) Pub. Date: Sep. 21, 2017

(54) STRUCTURE OF CHIP ON SOFT PANEL AND LIQUID CRYSTAL DISPLAY PANEL EQUIPPED WITH CHIP ON SOFT PANEL

(71) Applicant: Shenzhen China Star Optoelectronics Technology Co., Ltd., Shenzhen, Guangdong (CN)

(72) Inventors: Haiman SONG, Shenzhen, Guangdong (CN); Dongsheng GUO, Shenzhen, Guangdong (CN)

(73) Assignee: Shenzhen China Star Optoelectronics Technology Co., Ltd., Shenzhen, Guangdong (CN)

(21) Appl. No.: 14/905,798

(22) PCT Filed: Dec. 25, 2015
(86) PCT No.: PCT/CN2015/098985

§ 371 Date: Jan. 16, 2016

(30) Foreign Application Priority Data
Nov. 26, 2015 (CN) 201510843728.5

(51) Int. Cl. G02F 1/1345; H01L 23/00; G02F 1/1333

(52) U.S. Cl. CPC G02F 1/13452; G02F 1/13458; G02F 1/133345; H01L 24/48; H01L 2224/48227; H01L 2924/1426

(57) ABSTRACT

The invention discloses a structure of a chip on a soft panel, including a soft panel whereon a set of lead wires on an input terminal and a set of lead wires on an output terminal deposited, a bonding region formed on each end of the lead wires on the output terminal; a driver chip, which is deposited on the soft panel and connected to the lead wires on the input terminal and that on the output terminal electrically; a connection of the bonding region and an end of the corresponding lead wire is defined as A, and where the bonding region apart from the end of the corresponding lead wire on the output terminal is defined as B, a distance between A and B is L, an area of the bonding region is larger than that of the corresponding lead wire on the output terminal in the distance L.

### CROSS REFERENCE

This application claims the priority of Chinese Patent Application No. 201510843728.5, entitled “Structure of chip on soft panel and liquid crystal display panel with chip on soft panel”, filed on Nov. 26, 2015, the disclosure of which is incorporated herein by reference in its entirety.

### FIELD OF THE INVENTION

The present invention relates to a liquid crystal display technology field, and more particularly to a structure of a chip on a soft panel and a liquid crystal display panel equipped with the chip on a soft panel.

### BACKGROUND OF THE INVENTION

Types of packing a driver chip applied in a liquid crystal display (LCD) can be various, such as quad flat package (QFP), chip on glass (COG), tape automated bonding (TAB) and chip on film (COF), etc. Among them, COF structure of a chip on a soft panel has become the mainstream of packing techniques of LCD driver chips because of its pliability and narrower space provided.

In construction of a liquid crystal display, COF is equipped with a source electrode driver chip or a grid electrode driver chip. A lead wire (not shown in figures) on an input terminal that is connected to a printed circuit board (PCB) and a lead wire (not shown in figures) on an output terminal that is connected to a glass substrate of a liquid crystal display are disposed on COF, which can connect PCB and the glass substrate of a liquid crystal display panel electrically. The lead wire on the output terminal is taken as an example, it is connected to a transparent circuit on the glass substrate of a liquid crystal display panel, not only is the amount of wires huge, but also the arrangement is compact. Take a 32-in high definition liquid crystal display panel as an example, an input terminal of its source electrode driver chip has 131 lead wires, its output terminal has 1026 lead wires, a width of a COF soft panel can be around 40 mm, a width of each lead wire on each output terminal can be 0.0135 mm, a distance between adjacent wires can be 0.45 mm.

When bonding COF and the glass substrate of a liquid crystal panel, any shift can fail the match of the lead wires on the output terminal and the glass substrate so as to cause a short circuit and a poor bonding, resulting in lower yield.

### SUMMARY OF THE INVENTION

The aim of the invention is to provide a structure of a chip on a soft panel to solve a conventional technical issue, which is poor bonding caused by fine wires of a structure of a chip on a soft panel as well as a compact arrangement.

The present invention provides a structure of a chip on a soft panel, including a soft panel whereon a set of lead wires on an input terminal and a set of lead wires on an output terminal are deposited, a bonding region formed on each end of the lead wires on the output terminal; a driver chip, which is deposited on the soft panel and connected to the lead wires on the input terminal and that on the output terminal electrically; a connection of the bonding region and an end of the corresponding lead wire is defined as A, and where the bonding region apart from the end of the corresponding lead wire on the output terminal is defined as B, a distance between A and B is L, an area of the bonding region is larger than that of the corresponding lead wire on the output terminal in the distance L.

Among the bonding regions, bonding regions marked by odd numbers and those marked by even numbers are disposed alternately, the bonding regions marked by odd numbers are disposed along a first straight line in a row, the bonding regions marked by even numbers are disposed along a second straight line that is parallel to the first straight line in a row.

A shape of the bonding region is rectangle, triangle, round or other polygons.

A shape of the bonding region is triangle, one corner of the bonding region marked by odd numbers and an end of the corresponding lead wire on the output terminal are connected, a center of one side of the bonding region marked by even numbers and an end of the corresponding lead wire on the output terminal are connected.

A shape of the bonding region is triangle, one corner of the bonding region marked by even numbers and an end of the corresponding lead wire on the output terminal are connected, a center of one side of the bonding region marked by odd numbers and an end of the corresponding lead wire on the output terminal are connected.

Each of the lead wires on the input terminal includes a first connecting line and a first lead wire that are interconnected, the first connecting lines of the set of lead wires on the input terminal are disposed as a sector after stretching out of the driver chip, the first lead wires of the set of lead wires on the input terminal are parallel; each of the lead wires on the output terminal includes a second connecting line and a second lead wire that are interconnected, the second connecting lines of the set of lead wires on the output terminal are disposed as a sector after stretching out of the driver chip, the second lead wires of the set of lead wires on the input terminal are parallel.

The structure of a chip on a soft panel further includes an insulating layer, the insulating layer covers the soft panel, applied to shelter and protect the first connecting lines and the second connecting lines.

The invention further provides a liquid crystal display panel, including a printed circuit board, a glass substrate and a structure of a chip on a soft panel, the lead wire on an input terminal connected to the printed circuit board electrically, the lead wire on an output terminal connected to the glass substrate.

A set of substrate lead wires and substrate bonding regions that match the number of the substrate lead wire are disposed on the glass substrate, the number and arrangement of the substrate lead wire are same with that of the second lead wire; the substrate bonding regions are connected to ends of the substrate lead wires correspondingly, and shapes, sizes and arrangements are same with that of bonding regions of the structure of a chip on a soft panel; bonding regions of the substrate and the corresponding bonding regions of the structure of a chip on a soft panel are bonded as a whole.

The structure of a chip on a soft panel and the liquid crystal display panel improve the manipulation of bonding machines by disposing bonding regions which have larger areas, when bonding the structure of a chip on a soft panel and the glass substrate, even though a deviation exists, the poor bonding can be avoided as long as the deviation is limited in a range. Furthermore, bonding regions with larger areas further extend the area of contact between the structure of a chip on a soft panel and the glass substrate, resulting in better stability of physical and electrical connection. Moreover, bonding regions with larger areas can also be applied as test points, which can reduce lengths of lead wires and costs in manufacture.

### BRIEF DESCRIPTION OF THE DRAWINGS

In order to more clearly illustrate the embodiments of the present invention or prior art, the following figures will be described briefly in the embodiments or the prior art. It is obvious that the drawings are merely some embodiments of the present invention, those of ordinary skill in this field can obtain other figures according to these figures without paying the premise.

FIG. 1 is a structural diagram of a first embodiment according to a structure of a chip on a soft panel of the present invention;

FIG. 2 is a structural diagram of a second embodiment according to a structure of a chip on a soft panel of the present invention;

FIG. 3 is a structural diagram of a third embodiment according to a structure of a chip on a soft panel of the present invention;

FIG. 4 is a structural diagram of a liquid crystal display panel with the structure of a chip on a soft panel in FIG. 1.

### DETAILED DESCRIPTION OF PREFERRED EMBODIMENTS

Embodiments of the present invention are described in detail with reference to the accompanying drawings as follows. It is clear that the described embodiments are part of embodiments of the present invention, but not all embodiments. Based on the embodiments of the present invention, all other embodiments to those of ordinary skill in the premise of no creative efforts obtained should be considered within the scope of protection of the present invention.

The invention provides a structure of a chip on a soft panel, which can be applied in an electric device with a display panel, such as a mobile phone, a tablet, a laptop, a liquid crystal display, a liquid crystal television and a digital camera, etc. The embodiment takes a liquid crystal display panel as an example to describe merits of the invention.

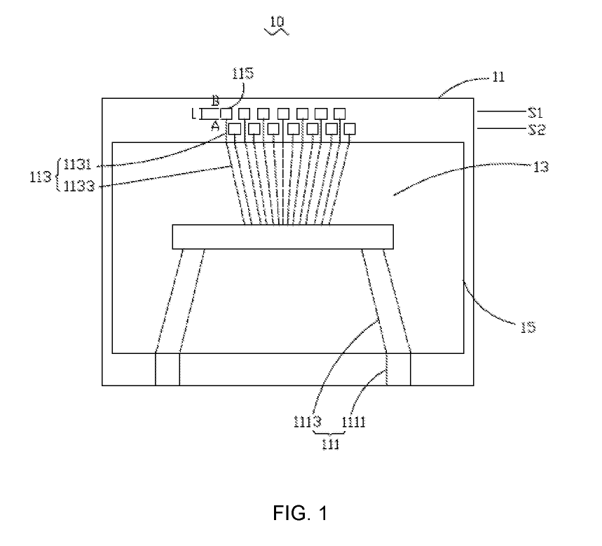

Please refer to FIG. 1, a structure of a chip 10 on a soft panel according to a first embodiment of the present invention includes a soft panel 11 and a driver chip 13. A set of lead wires 111 on an input terminal and a set of lead wires 113 on an output terminal are deposited on the soft panel 11. To be clear, for convenience of explanation, FIG. 1 is presented in a simplified way, the amount of lead wires has been cut off, and details unrelated to the description are glossed over. A bonding region 115 is formed on end of each of the lead wires 113 on the output terminal. The driver chip 13 is disposed on the soft panel 11 and connected to each lead wire 111 on the input terminal and lead wire 113 on the output terminal electrically. A driver chip 13 can be a source electrode driver chip or a grid electrode driver chip. A connection of the bonding region 115 and an end of the corresponding lead wire 113 on the output terminal is defined as A, and where the bonding region 115 apart from the end of the corresponding lead wire 113 on the output terminal is defined as B, a distance between A and B is L, an area of the bonding region 115 is larger than that of the corresponding lead wire 113 on the output terminal in the distance L. Compared with the finer lead wire 113 on the output terminal, the bonding region 115 with larger area is set to improve the manipulation of bonding machines, when bonding the structure of a chip 10 on a soft panel and the glass substrate, even though a deviation exists, the poor bonding can be avoided as long as the deviation is limited in a range. Furthermore, the bonding region 115 with larger area further extends the area of contact between the structure of a chip 10 on a soft panel and the glass substrate, resulting in better stability of physical and electrical connection. Moreover, bonding region 115 with larger area can also be applied as a test point, which can reduce lengths of lead wires and costs in manufacture.

Specifically, each of the bonding regions 115 is disposed alternately, in other words, bonding regions 115 marked by odd numbers and those marked by even numbers are disposed alternately, the bonding regions 115 marked by odd numbers are disposed along a first straight line in a row, the bonding regions 115 marked by even numbers are disposed along a second straight line that is parallel to the first straight line in a row. For instance, as shown in FIG. 1, bonding regions 115 marked by 1, 3, 5, 7, 9, 11 and 13 from left to right are disposed alternately, extending along the first straight line S1 in a row; bonding regions 115 marked by 2, 4, 6, 8, 10, 12 and 14 from left to right are disposed alternately, extending along a second straight line S2 that is parallel to the first straight line S1. The bonding regions 115 can utilize the space adequately between every two adjacent lead wires 113 on the output terminal in a form of zigzag, which can obtain larger bonding regions 115 without outspreading distance between each lead wire 113 on the output terminal, therefore, the size of the chip 10 on a soft panel will not be enlarged.

In the embodiment, a shape of each of the bonding regions 115 is rectangle. Similarly, in other substitutive embodiments, the bonding regions 115 can be round, polygon or any other irregular shapes, which can guarantee the bonding regions 115 have larger areas.

Each of the lead wires 111 on the input terminal includes first connecting lines 1111 and first lead wires 1113 that are interconnected, the first connecting lines 1111 of the set of lead wires 111 on the input terminal are disposed as a sector after stretching out of the driver chip 13, the first lead wires 1113 of the set of lead Wires 111 on the input terminal are parallel. Each of the lead wires 113 on the output terminal includes second connecting lines 1131 and second lead wires 1133 that are interconnected, the second connecting lines 1131 of the set of lead wires 113 on the output terminal are disposed as a sector after stretching out of the driver chip 13, the second lead wires 1133 of the set of lead wires 113 on the output terminal are parallel.

Furthermore, the structure of a chip 10 on a soft panel further includes an insulating layer 15, the insulating layer 15 covers the soft panel 11, applied to shelter and protect the first connecting lines 1111 and the second connecting lines 1131.

The structure of a chip 10 on a soft panel according to a first embodiment of the present invention improves the manipulation of bonding machines by disposing the bonding regions 115 with larger areas, when bonding the structure of a chip 10 on a soft panel and the glass substrate, even though a deviation exists, the poor bonding can be avoided as long as the deviation is limited in a range. Furthermore, the bonding regions 115 with larger areas further extend the area of contact between the structure of a chip 10 on a soft panel and the glass substrate, resulting in better stability of physical and electrical connection. Moreover, the bonding regions 115 with larger areas can also be applied as test points, which can reduce lengths of lead wires and costs in manufacture.

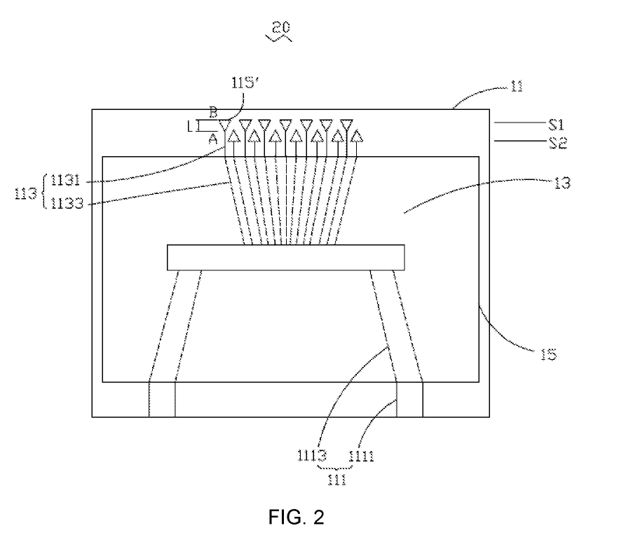

Referring to FIG. 2, a structure of a chip 20 on a soft panel according to a second embodiment of the present invention. The structure of a chip 20 on a soft panel is similar with the structure of a chip 10 in the first embodiment, difference appears in: the shape of bonding region 115′ of the structure of a chip 20 on a soft panel is triangle. In the embodiment, one corner of the bonding region 115′ marked by odd numbers and an end of the corresponding lead wire 113 on the output terminal are connected, a center of one side of the bonding region 115′ marked by even numbers and an end of the corresponding lead wire on the output terminal are connected. For instance, as shown in FIG. 2, one corner of each of the bonding regions 115′ marked by 1, 3, 5, 7, 9, 11 and 13 from left to right and an end of the corresponding lead wire 113 on the output terminal are connected, a center of one side of the bonding regions 115′ marked by 2, 4, 6, 8, 10, 12 and 14 from left to right and an end of the corresponding lead wire 113 on the output terminal are connected.

Similarly, in other substitutive embodiments, one corner of the bonding region 115′ marked by even numbers and an end of the corresponding lead wire 113 on the output terminal are connected, a center of one side of the bonding region 115′ marked by odd numbers and an end of the corresponding lead wire 113 on the output terminal are connected.

Similarly, in other substitutive embodiments, one corner of each of the triangular bonding regions 115′ and an end of the corresponding lead wire 113 on the output terminal are connected.

Similarly, in other substitutive embodiments, a center of one side of each of the triangular bonding regions 115′ and an end of the corresponding lead wire 113 on the output terminal are connected.

The structure of a chip 20 on a soft panel according to the second embodiment of the present invention improves the manipulation of a bonding machine by disposing the bonding regions 115′ with larger areas, when bonding the structure of a chip 20 on a soft panel and the glass substrate, even though a deviation exists, the poor bonding can be avoided as long as the deviation is limited in a range. Furthermore, the bonding regions 115′ with larger areas further extend the area of contact between the structure of a chip 20 on a soft panel and the glass substrate, resulting in better stability of physical and electrical connection. Moreover, bonding regions 115′ with larger areas can also be applied as test points, which can reduce lengths of lead wires and costs in manufacture.

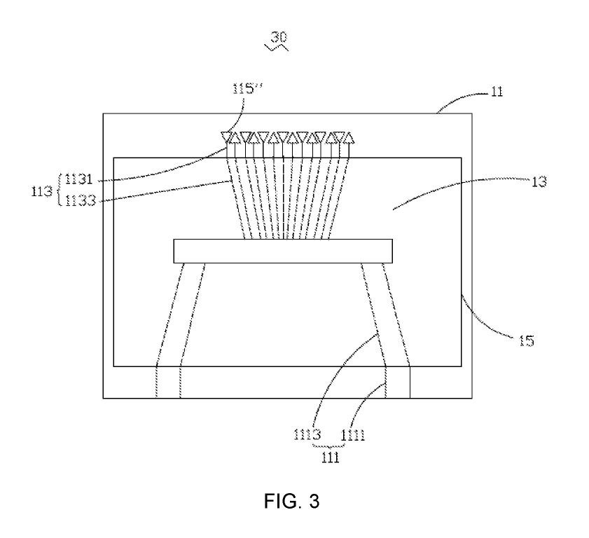

Referring to FIG. 3, a structure of a chip 30 on a soft panel according to a third embodiment of the present invention. The structure of a chip 30 on a soft panel is similar with the structure of a chip 20 in the second embodiment, difference appears in: bonding regions 115″ of the structure of a chip 30 on a soft panel are all disposed in one row.

The structure of a chip 30 on a soft panel according to the third embodiment of the present invention improves the manipulation of a bonding machine by disposing the bonding regions 115″ with larger areas, when bonding the structure of a chip 30 on a soft panel and the glass substrate, even though a deviation exists, the poor bonding can be avoided as long as the deviation is limited in a range. Furthermore, the bonding regions 115″ with larger areas further extend the area of contact between the structure of a chip 30 on a soft panel and the glass substrate, resulting in better stability of physical and electrical connection. Moreover, bonding regions 115″ with larger areas can also be applied as test points, which can reduce lengths of lead wires and costs in manufacture.

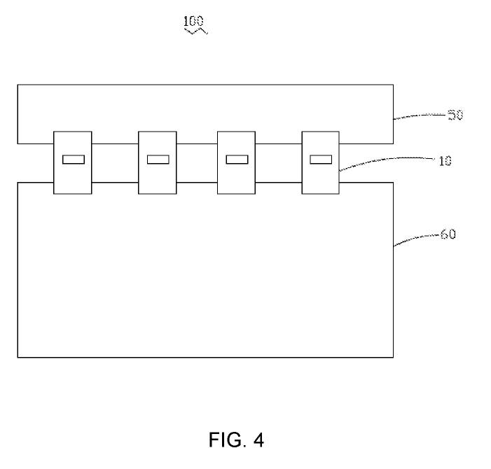

Referring to FIG. 4, the invention further provides a liquid crystal display panel 100, including a printed circuit board 50, a glass substrate 60 and one structure of a chip 10, 20 or 30 on a soft panel according to the embodiments above. The following is an illustration that a liquid crystal display panel 100 with the structure of a chip 10 on a soft panel according to the first embodiment. The lead wires 111 on the input terminal of the structure of a chip 10 on a soft panel are connected to the printed circuit board 50 electrically; the lead wires 113 on the output terminal of the structure of a chip 10 on a soft panel is connected to the glass substrate 60 physically and electrically.

Specifically, a set of substrate lead wires (not shown in figures) and bonding regions on a substrate that match the number of the lead wires on a substrate are disposed on the glass substrate 60, the amount and arrangement of the lead wires on a substrate are same with that of the second lead wires 1133; the bonding regions on a substrate are connected to ends of the lead wires on a substrate correspondingly, and shapes, sizes and arrangements are same with that of bonding regions 115 of the structure of a chip 10 on a soft panel; the bonding regions on a substrate and the corresponding bonding regions 115 of the structure of a chip 10 on a soft panel are bonded as a whole.

Similarly, in other substitutive embodiments, larger bonding regions can be disposed on ends of lead wires 111 on the input terminal of the structure of a chip 10 on a soft panel, equally, a bonding region can be disposed on the printed circuit board 50 correspondingly, in order to connect the two bonding regions physically and electrically.

The liquid crystal display panel 100 improves the manipulation of a bonding machines by disposing the bonding regions 115 with larger areas, when bonding the structure of a chip 10 on a soft panel and the glass substrate 60, even though a deviation exists, the poor bonding can be avoided as long as the deviation is limited in a range. Furthermore, the bonding regions 115 with larger areas further extend the area of contact between the structure of a chip 10 on a soft panel and the glass substrate, resulting in better stability of physical and electrical connection. Moreover, bonding regions 115 with larger areas can also be applied as test points, which can reduce lengths of lead wires and costs in manufacture.

Above are embodiments of the present invention, which do not limit the scope of the present invention. It is understandable in practical to the person who is skilled in the art that all or portion of the processes in the method according to the aforesaid embodiment can be accomplished. Any modifications, equivalent replacements or improvements within the spirit and principles of the embodiment described above should be covered by the protected scope of the invention.

What is claimed is:

1. A structure of a chip on a soft panel, wherein it comprises:
a soft panel whereon a set of lead wires on an input terminal and a set of lead wires on an output terminal are deposited, a bonding region is formed on each end of the lead wires on the output terminal;
a driver chip, which is deposited on the soft panel and connected to the lead wires on the input terminal and that on the output terminal electrically;
a connection of the bonding region and an end of the corresponding lead wire on the output terminal is defined as A, and where the bonding region apart from the end of the corresponding lead wire on the output terminal is defined as B, a distance between A and B is L, an area of the bonding region is larger than that of the corresponding lead wire on the output terminal in the distance L.

2. The structure of a chip on a soft panel according to claim 1, wherein among the bonding regions, bonding regions marked by odd numbers and those marked by even numbers are disposed alternately, the bonding regions marked by odd numbers are disposed along a first straight line in a row, the bonding regions marked by even numbers are disposed along a second straight line that is parallel to the first straight line in a row.

3. The structure of a chip on a soft panel according to claim 1, wherein a shape of the bonding region is rectangle, triangle, round or other polygons.

4. The structure of a chip on a soft panel according to claim 1, wherein a shape of the bonding region is triangle, one corner of the bonding region marked by odd numbers and an end of the corresponding lead wire on the output terminal are connected, a center of one side of the bonding region marked by even numbers and an end of the corresponding lead wire on the output terminal are connected.

5. The structure of a chip on a soft panel according to claim 1, wherein a shape of the bonding region is triangle, one corner of the bonding region marked by even numbers and an end of the corresponding lead wire on the output terminal are connected, a center of one side of the bonding region marked by odd numbers and an end of the corresponding lead wire on the output terminal are connected.

6. The structure of a chip on a soft panel according to claim 2, wherein each of the lead wires on the input terminal comprises a first connecting line and a first lead wire that are interconnected, the first connecting lines of the set of lead wires on the input terminal are disposed as a sector after stretching out of the driver chip, the first lead wires of the set of lead wires on the input terminal are parallel; each of the lead wires on the output terminal comprises a second connecting line and a second lead wire that are interconnected, the second connecting lines of the set of lead wires on the output terminal are disposed as a sector after stretching out of the driver chip, the second lead wires of the set of lead wires on the input terminal are parallel.

7. The structure of a chip on a soft panel according to claim 5, wherein the structure of a chip on a soft panel further comprises an insulating layer, the insulating layer covers the soft panel, applied to shelter and protect the first connecting lines and the second connecting lines.

8. A liquid crystal display panel, comprising a printed circuit board, a glass substrate and a structure of a chip on a soft panel, the lead wire on an input terminal connected to the printed circuit board electrically, the lead wire on an output terminal connected to the glass substrate; the structure of a chip on a soft panel comprising:
a soft panel whereon a set of lead wires on an input terminal and a set of lead wires on an output terminal are deposited, a bonding region formed on each end of the lead wires on the output terminal;
a driver chip, which is deposited on the soft panel and connected to the lead wires on the input terminal and that on the output terminal electrically;
wherein a connection of the bonding region and an end of the corresponding lead wire is defined as A, and where the bonding region apart from the end of the corresponding lead wire on the output terminal is defined as B, a distance between A and B is L, an area of the bonding region is larger than that of the corresponding lead wire on the output terminal in the distance L.

9. The liquid crystal display panel according to claim 8, wherein among the bonding regions, bonding regions marked by odd numbers and those marked by even numbers are disposed alternately, the bonding regions marked by odd numbers are disposed along a first straight line in a row, the bonding regions marked by even numbers are disposed along a second straight line that is parallel to the first straight line in a row.

10. The liquid crystal display panel according to claim 8, wherein a shape of the bonding region is rectangle, triangle, round or other polygons.

11. The liquid crystal display panel according to claim 8, wherein a shape of the bonding region is triangle, one corner of the bonding region marked by odd numbers and an end of the corresponding lead wire on the output terminal are connected, a center of one side of the bonding region marked by even numbers and an end of the corresponding lead wire on the output terminal are connected.

12. The liquid crystal display panel according to claim 8, wherein a shape of the bonding region is triangle, one corner of the bonding region marked by even numbers and an end of the corresponding lead wire on the output terminal are connected, a center of one side of the bonding region marked by odd numbers and an end of the corresponding lead wire on the output terminal are connected.

13. The liquid crystal display panel according to claim 9, wherein each of the lead wires on the input terminal comprises a first connecting line and a first lead wire that are interconnected, the first connecting lines of the set of lead wires on the input terminal are disposed as a sector after stretching out of the driver chip, the first lead wires of the set of lead wires on the input terminal are parallel; each of the lead wires on the output terminal comprises a second connecting line and a second lead wire that are interconnected, the second connecting lines of the set of lead wires on the output terminal are disposed as a sector after stretching out of the driver chip, the second lead wires of the set of lead wires on the input terminal are parallel.

14. The liquid crystal display panel according to claim 12, wherein the structure of a chip on a soft panel further comprises an insulating layer, the insulating layer covers the soft panel, applied to shelter and protect the first connecting lines and the second connecting lines.

15. The liquid crystal display panel according to claim 8, wherein a set of lead wires on a substrate and bonding regions on a substrate that match the number of the lead wires on a substrate are disposed on the glass substrate, the amount and arrangement of the lead wires on a substrate are same with that of the second lead wire; the bonding regions on a substrate are connected to ends of the lead wires on a substrate correspondingly, and shapes, sizes and arrangements are same with that of bonding regions of the structure of a chip on a soft panel; bonding regions of the substrate and the corresponding bonding regions of the structure of a chip on a soft panel are bonded as a whole.
